(19) United States
(12) Patent Application Publication
(10) Pub. No.: US 2024/0421196 A1
(43) Pub. Date: Dec. 19, 2024

(54) GaN SEMICONDUCTOR POWER TRANSISTOR WITH SLANTED GATE FIELD PLATE AND METHOD OF FABRICATION

(71) Applicant: GaN Systems Inc., Kanata (CA)

(72) Inventors: Abhinandan DIXIT, Kanata (CA); Jayasimha PRASAD, Upland, CA (US); Thomas MACELWEE, Nepean (CA); Vineet UNNI, Kanata (CA)

(21) Appl. No.: 18/209,128

(22) Filed: Jun. 13, 2023

(51) Int. Cl. H01L 29/40; H01L 23/31; H01L 29/20; H01L 29/66; H01L 29/778

(52) U.S. Cl. CPC H01L 29/402; H01L 23/3171; H01L 23/3192; H01L 29/2003; H01L 29/401; H01L 29/66462; H01L 29/7786

(57) ABSTRACT

A GaN semiconductor power transistor structure with a slanted gate field plate, and a method of fabrication are disclosed. The gate field plate comprises a gate metal field plate and slanted gate field plate structure formed using contact metal and/or interconnect metal. The slanted structure of the gate field plate is defined by etching of a dielectric layer having a graded composition, to form a slanted opening that is filled with conductive metal. The dielectric thickness under the gate field plate and the slant angle are configured to shape appropriately the electric field in the region between the gate and drain.

### CROSS-REFERENCE TO RELATED APPLICATION(S)

This application is related to U.S. patent application Ser. No. 18/129,457, filed Mar. 31, 2023, entitled “GaN Semiconductor Power Transistors With Stepped Metal Field Plates and Methods of Fabrication”, which is incorporated herein by reference in its entirety.

### TECHNICAL FIELD

This invention relates to Gallium Nitride (GaN) semiconductor power transistors, such as GaN HEMTs (High Electron Mobility Transistors), for high voltage and high current applications.

### BACKGROUND

In a field effect transistor, a field plate may be used to engineer or shape the electric field between electrodes, e.g. in the region around the gate and between the gate and the drain, of a power transistor to reduce the dynamic on-resistance and increase the device breakdown voltage.

The following references disclose examples of methods of forming stepped, tapered or slanted field plates for semiconductor power transistors:
U.S. Pat. No. 10,068,974B2 to Li et al., issued Sep. 4, 2018, entitled “Field Plate Power Device and Method of Manufacturing the same”.
US2008/0308813A1, to Suh et al., published Dec. 18, 2008, entitled “High Breakdown Enhancement Mode Gallium Nitride based High Electron Mobility Transistors with Integrated Slant Field Plate”;
US2021/0280678A1 to Patel, published Sep. 9, 2020, entitled “Greyscale Lithography for Double Slanted Gate Connected Field Plate”;
U.S. Pat. No. 8,530,978B1 to Chu et al., issued Sep. 10, 2013, entitled “High Current High Voltage GaN Field Effect Transistors and Method of Fabricating the Same”;
U.S. Pat. No. 10,068,974B2 issued Sep. 4, 2018, entitled “Field Plate Power Device and Method of Manufacturing the same”;
U.S. Pat. No. 9,929,243B1 to Corrion et al., issued Mar. 27, 2018, entitled “Stepped Field Palate Wide Bandgap Field-Effect Transistor and Method”;
U.S. Pat. No. 8,980,759B1 to Corrion et al., issued Mar. 17, 2015, entitled “Method of Fabricating Slanted Field-Plate GaN Heterojunction Field-Effect Transistor”;
U.S. Pat. No. 8,999,780B1 issued Apr. 7, 2015, to Khalil et al., entitled “Non-uniform two-dimensional electron gas profile in III-Nitride HEMT devices”;
U.S. Pat. No. 10,103,219B2 issued Oct. 16, 2018, to Pei et al., entitled “Power Semiconductor Device and Method for Manufacturing the same”.

Some of these device structures add significant process complexity and/or may not be compatible with existing fabrication processes offered by some semiconductor foundries.

In some device structures, gate metal is used to form a gate metal field plate (GFMP) For example, a stepped GMFP may be fabricated by gate metal deposition and etching, or by using a lift-off metallization process.

Lift-off refers to the process of patterning a masking material, e.g. photoresist, and depositing a thin film, e.g. gate metal, over the entire area, and then removing the masking material to leave behind the thin film only in the areas which were not masked. A disadvantage of a lift-off metallization process is the possibility of unwanted metal layers and haloes remaining on the surface of the wafer after lift-off. For high voltage applications, e.g. using GaN semiconductor HEMTs, the presence of unwanted metal extrusions can cause electric field crowding and potentially lead to dielectric failure.

There is a need for improved or alternative device structures and fabrication processes for power semiconductor transistors, e.g. GaN HEMTs, comprising gate metal field plates for high voltage applications.

### SUMMARY OF INVENTION

The present invention seeks to provide improved or alternative device structures and fabrication processes for GaN semiconductor power transistors, e.g. GaN HEMTs, comprising gate metal field plates, which overcome one or more of the above-mentioned issues.

Aspects of the invention provide a device structure comprising a GaN semiconductor power transistor, e.g. an enhancement-mode GaN HEMT, comprising a slanted gate field plate, and a method of fabrication.

One aspect provides a semiconductor device structure comprising an enhancement-mode GaN semiconductor power transistor comprising:
an epitaxial layer structure comprising a semiconductor substrate, a buffer layer, a GaN semiconductor heterostructure comprising a GaN channel layer and AlGaN barrier layer providing a 2 DEG active region;
a p-GaN layer patterned to define a p-GaN gate region;
a first passivation layer;
contact openings through the first passivation layer for source contacts and drain contacts;
ohmic contact metal within said contact openings which is patterned to form source contacts and drain contacts;
a second passivation layer;
a gate contact opening through the first and second passivation layers to the p-GaN gate region;
gate metal within the gate contact opening patterned to form a gate contact, the gate metal also forming a gate metal field plate in a region between the gate contact and the drain contact;
a third dielectric layer formed thereon having a graded composition;
openings etched through the third dielectric layer for a source contact, a drain contact and a gate contact, and another opening with slanted sidewalls etched through the third dielectric etched for forming a slanted gate field plate;
at least one layer of conductive metal filling each said openings to form the source contact, the drain contact, the gate contact and the slanted gate field plate.

The third dielectric layer comprises a graded composition wherein a bottom of the third dielectric layer has a denser composition than a top layer of the third dielectric layer, the graded composition providing an etch rate differential that defines the slant angle of the slanted gate metal field plate. The thickness of the third passivation layer and the slant angle of the slanted gate field plate are configured to shape an electric field under the slanted gate field plate between the gate contact and the drain contact.

Another aspect of the invention provides a method of fabricating a semiconductor device structure comprising an enhancement-mode GaN semiconductor power transistor comprising:
providing an epitaxial layer structure comprising a semiconductor substrate, a buffer layer, a GaN semiconductor heterostructure comprising a GaN channel layer and AlGaN barrier layer providing a 2 DEG active region, and a blanket p-GaN layer;
etching the blanket p-GaN layer to define p-GaN gate regions;
providing a first passivation layer covering the p-GaN gate regions;
etching contact openings through the first passivation layer for a source contact and a drain contact;
depositing and patterning ohmic contact metal to form the source contact and the drain contact;
providing a second passivation layer;
etching gate contact openings through the first and second passivation layers to the p-GaN gate regions;
depositing and patterning gate metal to form a gate contact and a gate metal field plate;
depositing a third dielectric layer overall, the third dielectric layer having a graded composition, a bottom of the third dielectric layer having a denser composition and slower etch rate than a top of the third dielectric layer;
performing a first etch process of the third dielectric layer to form contact openings for a source contact, a gate contact and a drain contact;
performing a second etch process of the third dielectric layer comprising a wet etch to form the slanted opening for the gate field plate.
depositing at least one layer of conductive metal to fill the contact openings for the source contact, gate contact, and drain contact and to form the slanted gate field plate.

The thickness of the third passivation layer and the slant angle of the slanted gate field plate are configured to shape an electric field under the slanted gate field plate between the gate contact and the drain contact.

The step of depositing at least one layer of conductive metal may comprise depositing a single metal layer, or a plurality of metal layers.

Depositing and patterning the gate metal to form the gate contact and the gate metal field plate may comprise a lift-off metal process. Depositing and patterning the gate metal to the form gate contact and the gate metal field plate comprises deposition and etching of the gate metal.

An enhancement-mode GaN semiconductor power transistor structure with a slanted gate field plate and a method of fabrication is disclosed. In example embodiments, the resulting slanted field plate structure provides an electric field distribution which provides a lower and smoother Coss curve, thus improving a Figure of Merit (FOM) of the device.

### BRIEF DESCRIPTION OF THE DRAWINGS

FIG. 1 shows a schematic cross-sectional view of a semiconductor device structure comprising an e-mode GaN HEMT comprising a gate metal contact and a gate metal field plate (GMFP) of a first example embodiment; and

FIGS. 2A to 2J show schematic cross-sectional views to illustrate steps in a method of fabrication of a semiconductor device structure comprising an e-mode GaN HEMT comprising a gate metal contact and a gate metal field plate (GMFP) of the first example embodiment;

FIG. 3 shows a schematic cross-sectional views to illustrate steps in a method of fabrication of a semiconductor device structure comprising an e-mode GaN HEMT comprising a gate metal contact and a gate metal field plate (GMFP) of a second example embodiment;

The foregoing and other features, aspects and advantages will be more apparent from the following detailed description, taken in conjunction with the accompanying drawings, of example embodiments, which description is by way of example only.

### DETAILED DESCRIPTION

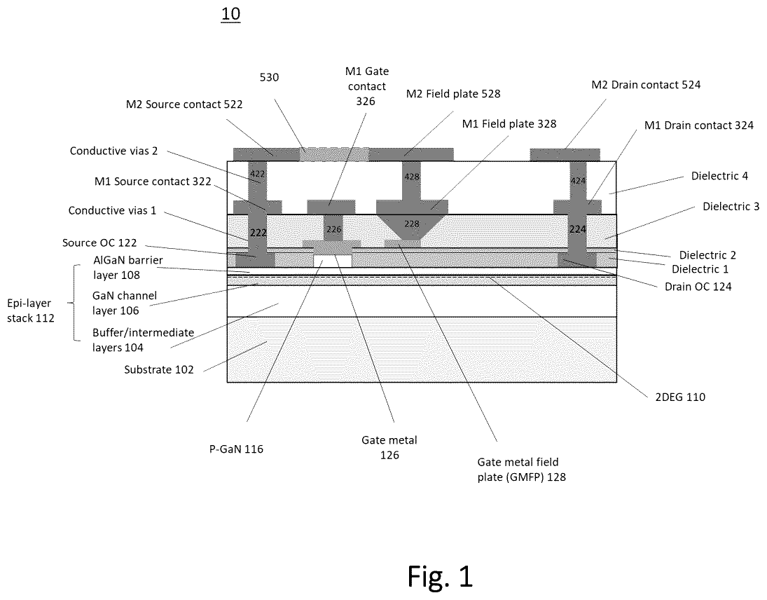

A schematic cross-sectional view of a device structure 10 comprising an enhancement mode (E-mode) GaN HEMT with a gate metal field plate of a first example embodiment is shown in FIG. 1. The GaN transistor is fabricated on a semiconductor substrate, e.g. a silicon substrate 102. The semiconductor layers comprise an epitaxial layer stack 112 comprising one or more buffer layers or intermediate layers 104, a GaN channel layer 106, and an overlying AlGaN barrier layer 108, which are formed epitaxially on the semiconductor substrate 102. For example, for a GaN-on-Silicon device structure, the substrate 102 may be p-doped silicon <111>. The latter may be referred to as the growth substrate. The GaN/AlGaN heterostructure layers 106/108 create a 2 DEG (two-dimensional electron gas) active area 110 in device regions of the GaN-on-Si substrate. The stack of GaN epitaxial layers that is formed on the silicon substrate, i.e. intermediate layers 104, GaN layer 106, and AlGaN layer 108, and any intervening layers not actually illustrated, will be referred to below as the “epi-layer stack” or “epi-stack” 112. After formation of the epi-layer stack 112, source, drain and gate electrodes are formed. For example, a conductive metal layer, e.g. a layer of aluminum/titanium (Al/Ti), which forms an ohmic contact (OC) with the underlying GaN heterostructure layer, is deposited and patterned to define a source electrode 122 and a drain electrode 124. A gate electrode 126 is defined over the channel region between the source and drain electrodes, e.g. a gate electrode comprising a Schottky metal, such as palladium (Pd) or Gold (Au). The gate metal may comprise multiple layers, e.g. a thin layer of titanium (Ti), a thin layer of platinum, and a thicker layer of gold (Au). This device structure can be fabricated as a depletion mode (D-mode) device which is normally-on, or as an enhancement mode (E-mode) device, which is normally-off. For an E-mode HEMT, the gate structure includes a p-type semiconductor layer 116 provided in the region under the gate electrode, e.g. a p-type GaN layer or p-type AlGaN layer under the gate metal 126, as illustrated schematically in FIG. 1. For a D-mode HEMT, the p-GaN layer is omitted, and the gate electrode is formed directly on the AlGaN barrier layer.

As illustrated schematically in FIG. 1, the lateral GaN HEMT device structure also comprises a gate metal field plate (GMFP) 128. The GFMP comprises the same metal layer or layers as the gate metal. e.g. a multilayer metal comprising Ti/Pt/Au. The gate metal 126 and GFMP 128 may be formed by metal deposition and etching, or by a lift-off metallization process.

There is an overlying interconnect structure comprising one or more conductive metal layers, and dielectric layers. The interconnect structure may comprise a plurality of conductive metal layers, and intervening (inter-metal) dielectric layers, to provide source, drain and gate contacts. For example, a first layer of metal, which may be referred to a contact metal provides a source contact 222 to the source OC 122 and a drain contact 224 to the drain OC 124, and a gate contact 226 to the gate metal 126. Another layer of metal, labelled M1, provides a larger area source contact 322, a drain contact 324, and a gate contact 326. The contact metal and metal M1 may each comprise multiple conductive metal layers or be formed from a single conductive metal layer. The contact metal also defines a slanted gate field plate 228 that contacts the GMFP 128. Metal M1 defines a field plate contact area 328. The interconnect structure illustrated schematically in FIG. 1 also includes a second metal layer, labelled M2, defining source contact area 522, drain contact area 524, and gate field plate contact area 528.

The GMFP 128 may be connected to source contact area 522 through metal M2 interconnect trace 530 to contact area 528, and through intervening metal layers including slanted field plate 228, as illustrated schematically in FIG. 1.

For simplicity, in the GaN transistor structure illustrated in FIG. 1, only a single source electrode, drain electrode and gate electrode is illustrated. Although only one transistor element is illustrated for device structure 10 in the simplified schematic cross-sectional view in FIG. 1, it will be appreciated that large area, multi-island lateral GaN HEMT may be provided. In a multi-island lateral GaN HEMT, multiple transistor islands or cells are connected in parallel to form a large gate width transistor, with high current carrying capability. An inactive region, or isolation region may surround the 2 DEG active device region. For example, the isolation region may be formed by ion implantation.

This device structure can be fabricated as a depletion mode (D-mode) device which is normally on, or as an enhancement mode (E-mode) device, which is normally off. For example, for a D-mode HEMT, the GaN heterostructure may comprise a layer of undoped GaN and a layer of undoped AlGaN, with the gate electrode formed directly on the AlGaN layer. For an enhancement mode (E-mode) HEMT, the GaN hetero-structure includes a p-type semiconductor layer 116 provided in the region under the gate electrode, e.g. p-type GaN layer or p-type AlGaN layer under the gate metal, as illustrated schematically in FIG. 1.

The GFMP 128 is formed from the gate metal, which may comprise multiple metal layers, e.g. Ti/Pt/Au. To form the slanted gate field plate structure 228, the composition of Dielectric 3 has a graded composition, so that wet etching can form a tapered opening with a defined slant angle. For example, the third dielectric layer (Dielectric 3) has a graded composition, wherein a bottom of the third dielectric layer has a denser composition and slower etch rate than a top of the third dielectric layer, and the top of the third dielectric layer is less dense and has a higher etch rate.

For example, the dielectric passivation layers may comprise silicon dioxide, silicon nitride, silicon oxynitride and combinations thereof to provide the appropriate thicknesses and compositions. The structures shown in the drawings are simplified schematic representations and thicknesses and lateral dimensions are not drawn to scale.

For GaN HEMTs having a higher 2 DEG density, insufficient thicknesses of dielectric under the GFMP can lead to degradation of the dielectric, which may create a leakage path. For example, if the thickness of Dielectric 1, e.g. SiN, under the GMFP is too thin, e.g. ≤100 nm, this may be insufficiently thick for a device having a higher 2 DEG density at the AlGaN/GaN interface. By choosing an appropriate slant angle, the dielectric thicknesses under a slanted gate field plate can be controlled, so that the electric field distribution can be optimized by suppressing the magnitude of the vertical electric field, which helps to reduce leakage, and improve the robustness and lifespan of the device.

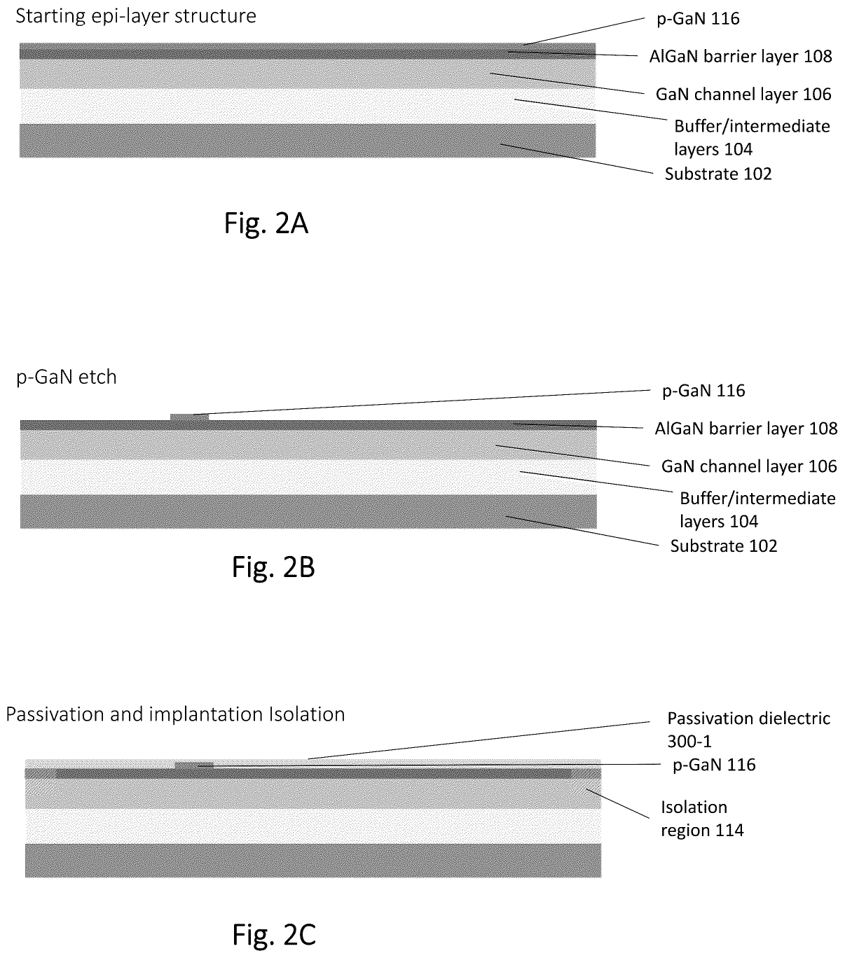

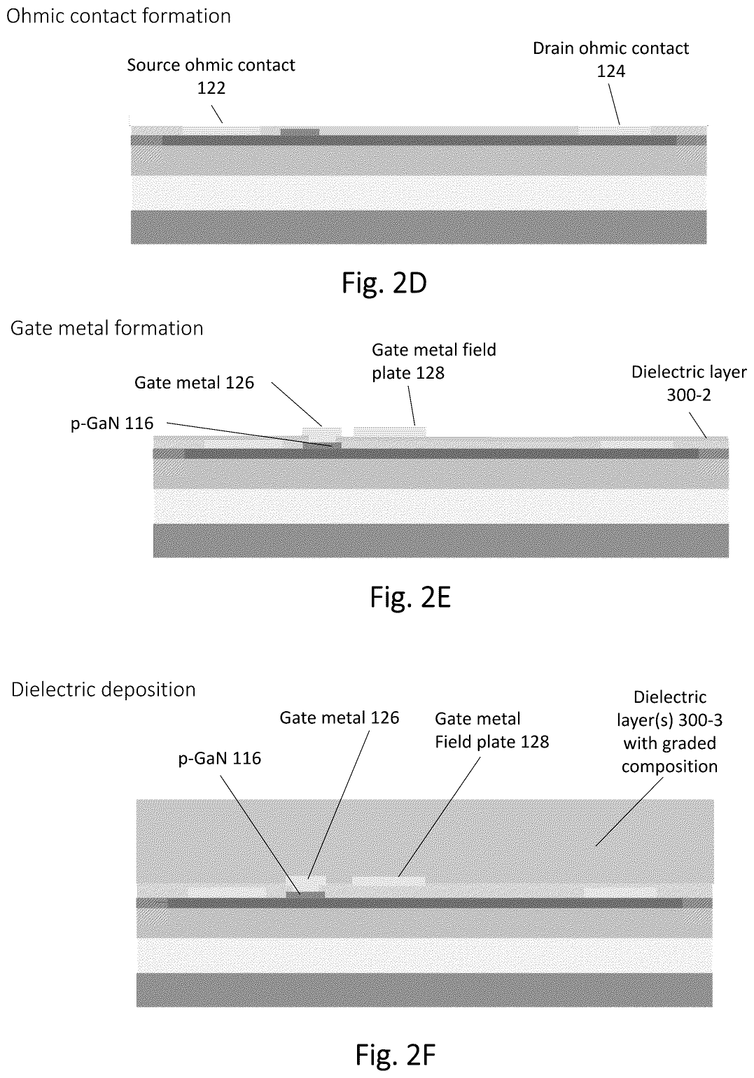

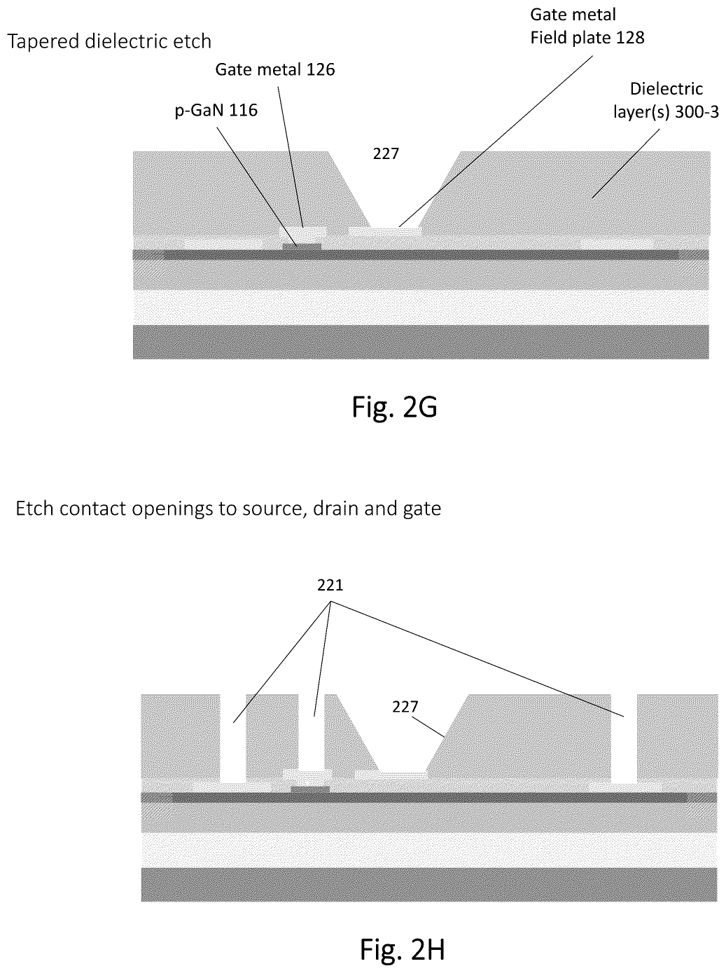

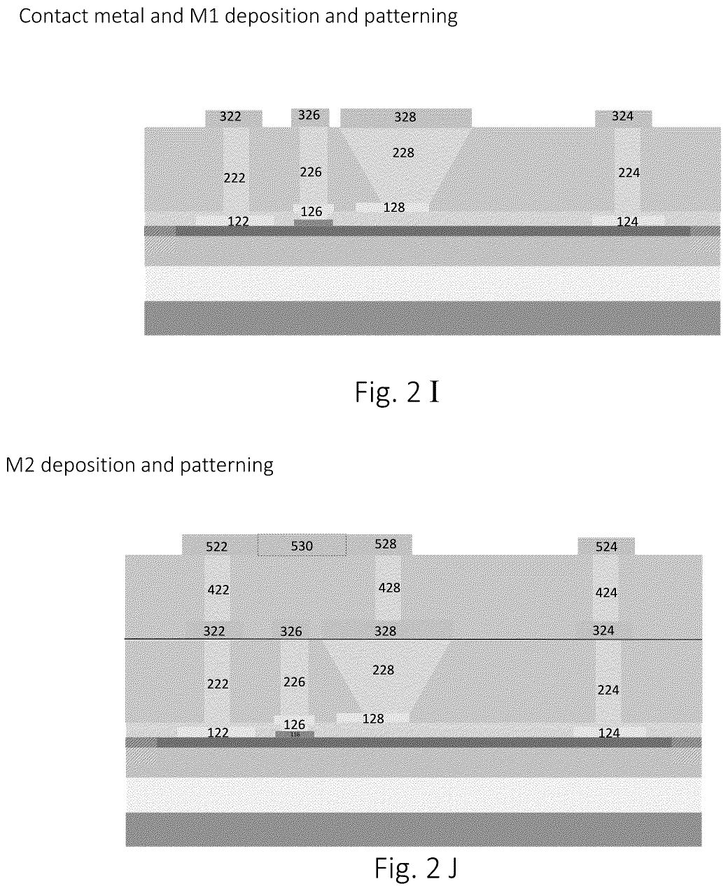

FIGS. 2A to 2J shows schematic cross-sectional views to illustrate steps in an embodiment of a method of fabrication of a semiconductor device structure comprising an e-mode GaN HEMT comprising a gate metal contact and a gate metal field plate (GMFP) of the example embodiment shown in FIG. 1.

As illustrated schematically in FIG. 2A, in fabrication of GaN HEMTs for high voltage applications, the starting wafer may be an epitaxial wafer comprising a silicon substrate 102, and a GaN semiconductor epitaxial layer stack comprising one or more buffer/intermediate layers 104, a GaN channel layer 106, and an overlying AlGaN barrier layer 108. The GaN/AlGaN heterostructure layers create a 2 DEG active region for device regions of the GaN-on-Si substrate. The epitaxial layer stack for enhancement mode GaN HEMTs comprising a p-GaN gate structure may include a blanket layer of p-GaN. A first step in the process is a p-GaN gate etch that defines the p-GaN gate area 116 for each transistor element, as illustrated schematically in FIG. 2B. Careful control of device processing is required to maintain the micro-structural quality of the semiconductor layers of the starting wafer. For example, exposure of the semiconductor layers of AlGaN and p-GaN during device processing can create defect or trap states, which potentially lead to degradation of key static and dynamic electric parameters. As illustrated schematically in FIG. 2C, it is therefore desirable to provide a first dielectric or passivation layer 300-1 over the p-GaN gate structures and over the AlGaN barrier layer prior to formation of ohmic contacts for the source and drain, and prior to providing the gate metal for the gate structure and gate metal field plate. After providing the passivation layer 300-1, an isolation region 114 may be provided around the active region, e.g. an ion implantation may be performed to form implantation isolation regions 114, surrounding the active region.

After forming the passivation layer 300-1, as illustrated schematically in FIG. 2D, openings are made in the passivation layer 300-1 and a source ohmic contact 122 and a drain ohmic contact 124 are formed, by deposition and etching of the source and drain ohmic contact metal. After providing a second dielectric or passivation layer 300-2, a gate contact opening is made, and gate metal is provided by deposition and etch back, or using a lift-off process, as illustrated schematically in FIG. 2E. The gate is patterned to form a gate contact 126 and a gate metal field plate 128

Then, as illustrated schematically in FIG. 2F, a third dielectric layer 300-3 is then deposited to provide a required thickness of dielectric for forming an opening that will be used to define the structure of the slanted gate field plate 228. The third dielectric layer 300-3 is deposited with a graded composition, e.g. which is denser at the bottom and less dense at the top. The process then proceeds with a dielectric etch as illustrated schematically in FIG. 2G to form a tapered opening. The graded composition of the third dielectric layer 300-3 allows for wet etching of the third dielectric layer 300-3 to form a tapered opening with a pre-determined sidewall slant angle. The lower density composition at the top etches faster than the higher density composition at the bottom. The composition of the third dielectric layer is varied from the bottom to the top to control the etch rate and forms tapered sidewalls 227.

Contact openings 221 for the source, drain and gate are defined, e.g. by dry etching as illustrated schematically in FIG. 2H.

These etch steps provide openings for a source contact, a drain contact, a gate contact, and a slanted metal field plate.

A contact metal deposition step may be used to form a source contact 222, a drain contact 224, a gate contact 226 and slanted gate field 228. A first metallization layer M1 is then deposited and patterned to provide contact areas for each, as illustrated schematically in FIG. 2I, comprising a source contact area 322, a gate contact area 226, a gate metal field plate contact area 328 and a drain contact area 324.

If required, a second level interconnect may be provided, by depositing a fourth dielectric layer (intermetal dielectric) 300-4, etching contact openings, and forming a second metallization layer M2 to fill the contact openings and form M2 contact areas. As show schematically in FIG. 2J, comprising source contact 422/522, drain contact 424/524, gate metal field plate contact 428/528. The gate metal field plate contact may be connected to source by region 530 of M2.

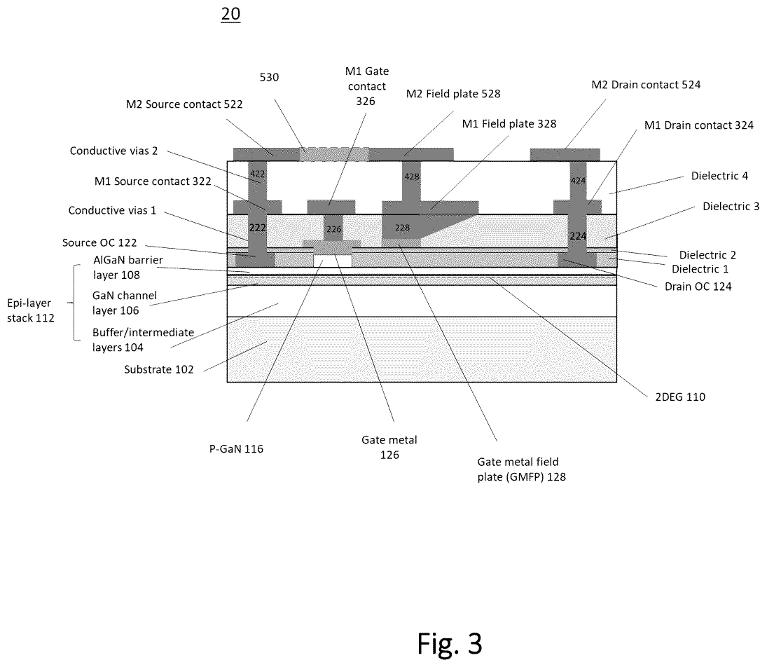

A schematic cross-sectional view of a device structure 20 comprising an enhancement mode (E-mode) GaN HEMT with a gate metal field plate of a second example embodiment is shown in FIG. 3. Corresponding parts are labelled with the same reference numerals as in FIG. 1. The device structure 20 shown schematically in FIG. 3 differs from the device structure 10 shown schematically in FIG. 1, in that the opening in dielectric 3 for the gate metal field plate 228-2 has a different lateral profile, to form a slanted field plate as illustrated schematically in FIG. 3, which tapers towards the drain region.

In the example embodiments illustrated schematically in FIG. 1 and FIG. 3, the slant angle provides a smooth taper of the dielectric thickness under the field plate in the direction of the drain. In alternative embodiments, the gate metal field plate may have a more complex shape, which is controlled by grading of the composition of dielectric 3 with thickness, so that the etch rate of dielectric 3 is dependent on thickness, to control the slant angle of the opening in which the gate mental field plate is formed.

By choosing an appropriate slant angle, and dielectric thicknesses under a slanted field plate, the electric field distribution can be optimized by suppressing the magnitude of the vertical electric field, which helps to reduce leakage, and improve the robustness and lifespan of the device.

The above referenced related U.S. patent application Ser. No. 18/129,457, filed Mar. 31, 2023, entitled “GaN Semiconductor Power Transistors With Stepped Metal Field Plates and Methods of Fabrication” discloses power semiconductor structures of example embodiments comprising stepped metal field plates. A GaN semiconductor power transistor of example embodiments comprising slanted gate metal field plates, fabricated as disclosed herein, may provide an improved E-field distribution, e.g. a lower and smoother Coss curve, to provide an improved Figure of Merit.

Although example embodiments have been described and illustrated in detail, it is to be clearly understood that the same is by way of illustration and example only and not to be taken by way of limitation, the scope of the present invention being limited only by the appended claims.

1. A semiconductor device structure comprising an enhancement-mode GaN semiconductor power transistor comprising:
an epitaxial layer structure comprising a semiconductor substrate, a buffer layer, a GaN semiconductor heterostructure comprising a GaN channel layer and AlGaN barrier layer providing a 2 DEG active region;
a p-GaN layer patterned to define a p-GaN gate region;
a first passivation layer;
contact openings through the first passivation layer for source contacts and drain contacts;
ohmic contact metal within said contact openings which is patterned to form source contacts and drain contacts;
a second passivation layer;
a gate contact opening through the first and second passivation layers to the p-GaN gate region;
gate metal within the gate contact opening patterned to form a gate contact, the gate metal also forming a gate metal field plate in a region between the gate contact and the drain contact;
a third dielectric layer formed thereon having a graded composition;
openings etched through the third dielectric layer for a source contact, a drain contact and a gate contact, and another opening with slanted sidewalls etched through the third dielectric etched for forming a slanted gate field plate;
at least one layer of conductive metal filling each said openings to form the source contact, the drain contact, the gate contact and the slanted gate field plate.

2. The semiconductor device structure of claim 1, wherein a thickness and the graded composition of the third dielectric layer are configured to shape an electric field under the slanted gate field plate, between the gate contact and the drain contact.

3. The semiconductor device structure of claim 1, wherein a thickness of the third dielectric passivation layer and the slant angle of the slanted gate field plate are configured to shape an electric field under the slanted gate field plate between the gate contact and the drain contact.

4. The semiconductor device structure of claim 1, wherein the least one layer of conductive metal comprises depositing a single metal layer.

5. The semiconductor device structure of claim 1, wherein the at least one layer of conductive metal comprises depositing a plurality of metal layers.

6. The semiconductor device structure of claim 1, comprising an interconnect trace connecting the source contact and the slanted gate field plate.

7. The semiconductor device structure of claim 1, wherein the gate metal contact and gate metal field plate is formed by a lift-off metal process.

8. The semiconductor device structure of claim 1, wherein the gate metal contact and gate metal field plate is formed by deposition and etching of the gate metal.

9. The semiconductor device structure of claim 1, wherein the third dielectric layer comprises a graded composition wherein a bottom of the third dielectric layer has a denser composition than a top layer of the third dielectric layer, the graded composition providing an etch rate differential that defines the slant angle.

10. The semiconductor device structure of claim 1, wherein the third dielectric layer comprises a plurality of dielectric layers deposited sequentially to provide said graded composition.

11. A method of fabricating an enhancement-mode GaN semiconductor power transistor comprising:
providing an epitaxial layer structure comprising a semiconductor substrate, a buffer layer, a GaN semiconductor heterostructure comprising a GaN channel layer and AlGaN barrier layer providing a 2 DEG active region, and a blanket p-GaN layer;
etching the blanket p-GaN layer to define p-GaN gate regions;
providing a first passivation layer covering the p-GaN gate regions;
etching contact openings through the first passivation layer for a source contact and a drain contact;
depositing and patterning ohmic contact metal to form the source contact and drain contact;
providing a second passivation layer;
etching gate contact openings through the first and second passivation layers to the p-GaN gate regions;
depositing and patterning gate metal to form a gate contact and a gate metal field plate;
depositing a third dielectric layer overall, the third dielectric layer having a graded composition, a bottom of the third dielectric layer having a denser composition and slower etch rate than a top of the third dielectric layer;
performing a first etch process of the third dielectric layer to form contact openings for a source contact, a gate contact and a drain contact;
performing a second etch process of the third dielectric layer comprising a wet etch to form a slanted opening for a slanted gate field plate.
depositing at least one layer of conductive metal to fill the contact openings for the source contact, gate contact, and drain contact and to form the slanted gate field plate.

12. The method of claim 11, wherein a thickness of the third dielectric passivation layer and a slant angle of the slanted gate field plate are configured to shape an electric field under the slanted gate field plate between the gate contact and the drain contact.

13. The method of claim 11, wherein the step of depositing at least one layer of conductive metal comprises depositing a single metal layer.

14. The method of claim 11, wherein the step of depositing at least one layer of conductive metal comprises depositing a plurality of metal layers.

15. The method of claim 11, wherein depositing and patterning gate metal to form the gate contact and the gate metal field plate comprises a lift-off metal process.

16. The method of claim 11, wherein depositing and patterning gate metal to the form gate contact and the gate metal field plate comprises deposition and etching of the gate metal.
